(19) United States
(12) Patent Application Publication
(10) Pub. No.: US 2025/0232903 A1
(43) Pub. Date: Jul. 17, 2025

(54) SOLENOID CONTROLLER

(71) Applicant: LG INNOTEK CO., LTD., Seoul (KR)

(72) Inventors: Won Kyu KIM, Seoul (KR); In Seok LIM, Seoul (KR); Sun Mi JUNG, Seoul (KR)

(73) Assignee: LG INNOTEK CO., LTD., Seoul (KR)

(21) Appl. No.: 18/854,761

(22) PCT Filed: Apr. 7, 2023
(86) PCT No.: PCT/KR2023/004702

§ 371 Date: Oct. 7, 2024

(30) Foreign Application Priority Data
Apr. 8, 2022 (KR) 10-2022-0043967

(51) Int. Cl. H01F 7/06; H03K 17/687

(52) U.S. Cl. CPC H01F 7/064; H03K 17/6871; H03K 2217/0063; H03K 2217/0072

(57) ABSTRACT

A solenoid controller according to an embodiment of the present invention comprises: a switching unit for outputting a voltage input from a power supply unit to a solenoid; a first clamping element for connecting one end of the solenoid with the power supply unit; and a second clamping element for connecting the one end of the solenoid to the ground, wherein the clamping voltage of the first clamping element is higher than the voltage of the power supply unit.

### TECHNICAL FIELD

The present invention relates to a solenoid controller, and more specifically, to a solenoid controller with improved solenoid response and a vehicle motor.

### BACKGROUND ART

According to the driving method of automobiles, it is divided into 2WD (wheel-drive), which is front-wheel drive or rear-wheel drive, and 4WD, which is 4-wheel drive. 4WD is also called AWD. Since all four wheels are driven in the four-wheel drive system rather than the two-wheel drive system, more stable operation is possible compared to the two-wheel drive system. However, four-wheel drive has the disadvantage of requiring greater power compared to two-wheel drive because all four wheels must be driven. Vehicles capable of four-wheel drive are divided into full time 4WD, which always drives four wheels, and part time 4WD, which selectively drives two-wheel drive and four-wheel drive. Part time 4WD can be divided into manual, mechanical, vacuum, and electronic types. When selecting two-wheel drive and four-wheel drive, a method of switching with a motor using a solenoid valve is used.

When using a solenoid, since an induced voltage is generated by the inductor of the solenoid, as shown in FIGS. 1 and 2, a freewheeling diode can be used to reduce the induced voltage that occurs by the electromagnet solenoid. When the electromagnet solenoid is turned off, a closed loop is formed between the freewheeling diode and the electromagnet solenoid, thereby minimizing the induced voltage, but there is a time delay in current consumption due to the time constant due to the inductance and resistance of the electromagnet solenoid. The residual current caused by the delay in current consumption causes a delay in the solenoid return response, causes a delay in changing to 2WD and 4WD, and has an adverse effect on the fuel efficiency of the vehicle.

### DETAILED DESCRIPTION OF THE INVENTION

### Technical Subject

The technical problem to be solved by the present invention is to provide a solenoid controller and a vehicle motor with improved solenoid response.

### Technical Solution

In order to solve the above technical problem, a solenoid controller according to an embodiment of the present invention comprises: a switching unit for outputting a voltage being inputted from a power supply unit to a solenoid; a first clamping element for connecting one end of the solenoid with the power supply unit; and a second clamping element for connecting the one end of the solenoid to the ground, wherein the clamping voltage of the first clamping element is higher than the voltage of the power supply unit.

In addition, when the power of the power supply unit is not applied to the solenoid by the switching unit, if the magnitude of the induced voltage being generated in the solenoid corresponds to between the clamping voltage and the voltage of the power supply unit, current may be discharged toward the power supply unit through the first clamping element.

In addition, when the power of the power supply unit is not applied to the solenoid by the switching unit, if the magnitude of the induced voltage being generated in the solenoid is greater than the clamping voltage, then current can be discharged toward the ground through the second clamping element.

In addition, when the power of the power supply unit is not applied to the solenoid by the switching unit, if the magnitude of the induced voltage being generated in the solenoid is smaller than the voltage of the power supply unit, then current can be discharged to the ground through the switching unit.

In addition, the first clamping element and the second clamping element may include at least one of a Zener diode or a TVS diode.

In addition, the first clamping element has an anode being connected to one end of the solenoid and a cathode being connected to the power supply unit, and the second clamping element may have a cathode being connected to one end of the solenoid and an anode being connected to the ground.

In addition, the power supply unit may include a battery.

In addition, the switching unit may include a plurality of high-side switches and a plurality of low-side switches conducting complementarily to one another.

In addition, the switching unit comprises: a first upper switch and a first low-side switch being connected to the power supply unit; and a second high-side switch and a second low-side switch being connected to the power supply unit, wherein a node between the first high-side switch and the first low-side switch is connected to one end of the solenoid, and wherein a node between the second high-side switch and the second low-side switch may be connected to the other end of the solenoid.

In addition, when the solenoid is turned off, the first high-side switch and the second low-side switch can be turned off.

In order to solve the above technical problem, a solenoid motor according to an embodiment of the present invention comprises: a solenoid being driven according to a voltage input; and a solenoid controller that controls the solenoid, wherein the solenoid controller comprises: a switching unit that outputs the voltage being inputted from the power supply unit to a solenoid; a first clamping element connecting one end of the solenoid and the power supply unit; and a second clamping element connecting one end of the solenoid to the ground, and wherein the clamping voltage of the first clamping element is higher than the voltage of the power supply unit.

In addition, when the power of the power supply unit is not applied to the solenoid by the switching unit, if the magnitude of the induced voltage being generated in the solenoid corresponds to between the clamping voltage and the voltage of the power supply unit, current is discharged toward the power supply unit through the first clamping element; if the magnitude of the induced voltage being generated in the solenoid is greater than the clamping voltage, current is discharged toward the ground through the second clamping element; and if the magnitude of the induced voltage being generated in the solenoid is smaller than the voltage of the power supply unit, current may be discharged to the ground through the switching unit.

In addition, the first clamping element and the second clamping element may include at least one of a Zener diode or a TVS diode.

### Advantageous Effects

According to embodiments of the present invention, the residual current time can be reduced. The OFF operation time of the electromagnet solenoid is also improved as much as the residual current time, which has the effect of improving the responsiveness of the electromagnetic solenoid and improving fuel efficiency.

### BRIEF DESCRIPTION OF DRAWINGS

FIGS. 1 and 2 are circuit diagrams of a solenoid controller according to a comparative example of the present invention.

FIG. 3 is a block diagram of a solenoid controller according to an embodiment of the present invention.

FIG. 4 is a circuit diagram of a solenoid controller according to an embodiment of the present invention.

FIGS. 5 to 7 are diagrams for explaining a solenoid controller according to an embodiment of the present invention.

FIG. 8 is a block diagram of a vehicle motor according to an embodiment of the present invention.

### BEST MODE

Hereinafter, preferred embodiments of the present invention will be described in detail with reference to the accompanying drawings.

However, the technical idea of the present invention is not limited to some embodiments to be described, but may be implemented in various forms, and within the scope of the technical idea of the present invention, one or more of the constituent elements may be selectively combined or substituted between embodiments.

In addition, the terms (including technical and scientific terms) used in the embodiments of the present invention, unless explicitly defined and described, can be interpreted as a meaning that can be generally understood by a person skilled in the art, and commonly used terms such as terms defined in the dictionary may be interpreted in consideration of the meaning of the context of the related technology.

In addition, terms used in the present specification are for describing embodiments and are not intended to limit the present invention. In the present specification, the singular form may include the plural form unless specifically stated in the phrase, and when described as “at least one (or more than one) of A and B and C”, it may include one or more of all combinations that can be combined with A, B, and C.

In addition, in describing the components of the embodiment of the present invention, terms such as first, second, A, B, (a), and (b) may be used. These terms are merely intended to distinguish the components from other components, and the terms do not limit the nature, order or sequence of the components.

And, when a component is described as being ‘connected’, ‘coupled’ or ‘interconnected’ to another component, the component is not only directly connected, coupled or interconnected to the other component, but may also include cases of being ‘connected’, ‘coupled’, or ‘interconnected’ due that another component between that other components.

In addition, when described as being formed or arranged in “on (above)” or “below (under)” of each component, “on (above)” or “below (under)” means that it includes not only the case where the two components are directly in contact with, but also the case where one or more other components are formed or arranged between the two components. In addition, when expressed as “on (above)” or “below (under)”, the meaning of not only an upward direction but also a downward direction based on one component may be included.

Modified embodiments according to the present embodiment may include some components of each embodiment and some components of other embodiments together. That is, a modified embodiment may include one embodiment among various embodiments, but some components may be omitted and some components of other corresponding embodiments may be included. Or, it may be the other way around. Features, structures, effects, and the like to be described in the embodiments are included in at least one embodiment, and are not necessarily limited to only one embodiment. Furthermore, the features, structures, and effects illustrated in each embodiment can be combined or modified with respect to other embodiments by those skilled in the art in the field to which the embodiments belong. Therefore, contents related to these combinations and modifications should be construed as being included in the scope of the embodiments.

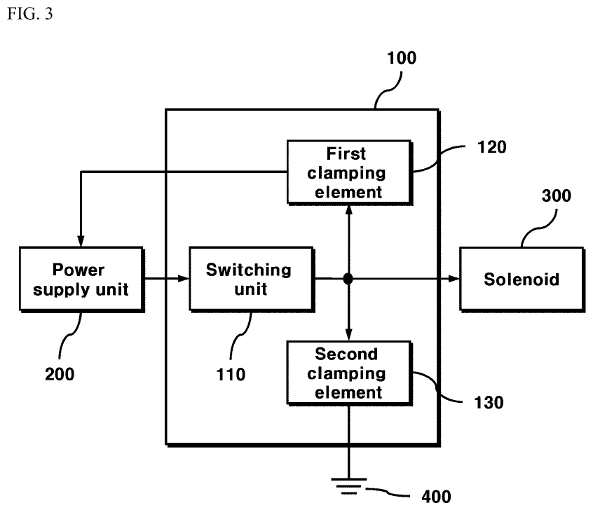

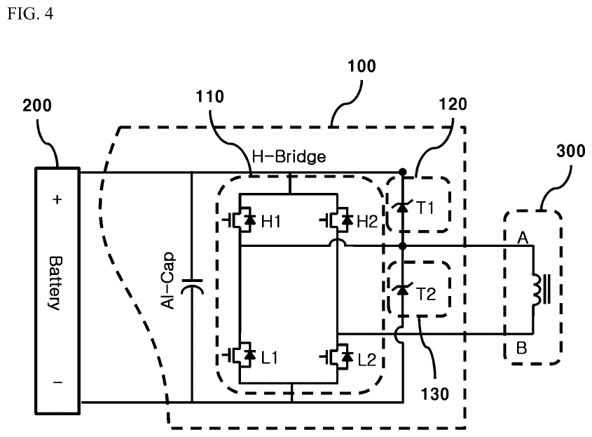

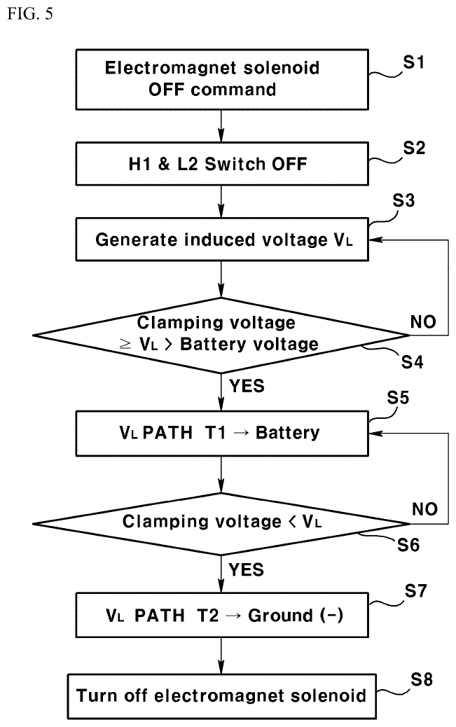

FIG. 3 is a block diagram of a solenoid controller according to an embodiment of the present invention; FIG. 4 is a circuit diagram of a solenoid controller according to an embodiment of the present invention; and FIGS. 5 to 7 are diagrams for explaining a solenoid controller according to an embodiment of the present invention.

The solenoid controller 100 according to an embodiment of the present invention is configured with a switching unit 110, a first clamping element 120, and a second clamping element 130; and it may include a controller for controlling the switching unit 110 (not shown), a gate driver (not shown), an input capacitor, and the like may be included. The solenoid 300 according to an embodiment of the present invention can be applied to a vehicle motor. For example, it can be applied to a motor that switches the driving method of a vehicle between two-wheel drive (2WD) and four-wheel drive (4WD). According to turning on and off of the solenoid, a switching operation can be performed to deliver the power of the vehicle to only the front or rear wheels or to all four wheels.

The switching unit 110 outputs the voltage being inputted from the power supply unit 200 to the solenoid 300. The solenoid 300 wound with a coil in a cylindrical shape may be an electromagnetic solenoid that generates a magnetic field in the direction penetrating the inside of the coil so that when a current flows by a voltage applied to the solenoid 300 the magnetic material located inside moves linearly in an axial direction of the cylinder due to the magnetic field. Solenoids can be implemented as solenoid motors, solenoid valves, solenoid actuators, and the like using such a driving method.

Depending on the on-off operation of the switching unit 110, the voltage being inputted from the power supply unit 200 may be applied to the solenoid 300 or blocked. In order to turn on the solenoid 300, the switching unit 110 may be driven so that the voltage of the power supply unit 200 is outputted to the solenoid 300. Here, the power supply unit 200 may include a battery. The battery may be a vehicle battery. While voltage is being applied to the solenoid 300, if a control command to turn off the solenoid 300 is inputted, the switching unit 110 may block the path through which voltage is applied from the power supply unit 200 to the solenoid 300. At this time, even after the path through which voltage is applied from the power supply unit 200 to the solenoid 300 is blocked, there may be a residual current flowing in the solenoid 300, and an induced voltage is generated by the inductance of the solenoid 300 through which the residual current flows. In this way, burning damage may occur in the switching unit 110 due to the generated induced voltage. Therefore, a configuration is needed to consume the induced voltage being generated in the solenoid 300.

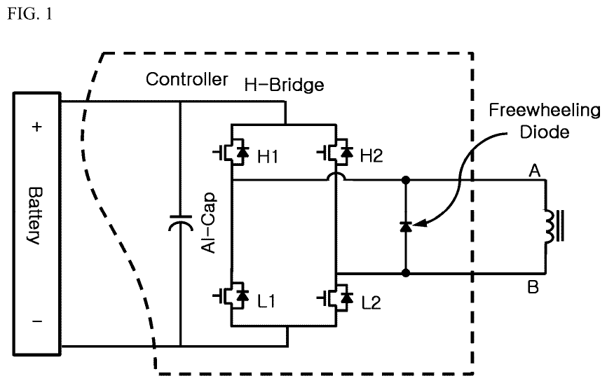

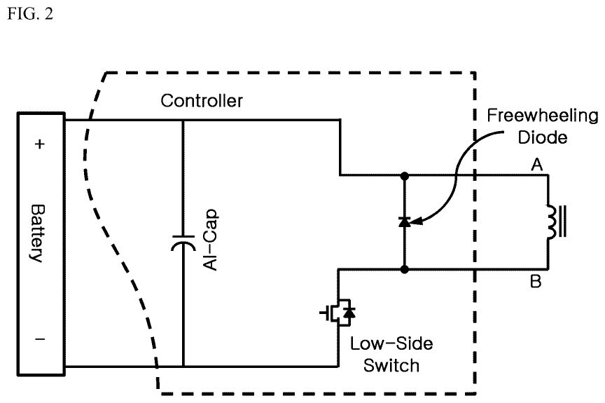

In order to consume the induced voltage being generated in the solenoid, a freewheeling diode can be used, as shown in FIGS. 1 and 2.

As shown in FIG. 1, it is configured with an H-BRIDGE switching unit and a freewheeling diode for driving the solenoid, so that voltage can be applied to the electromagnet solenoid. When the H1 and L2 switches are turned on, voltage is applied to the solenoid. If the H1 and L2 switches are turned off to turn off the solenoid while voltage is being applied to the solenoid, voltage application from the battery, which is the power supply unit, is blocked, but an induced voltage is generated inside the solenoid due to the inductance value and residual current of the solenoid. A freewheeling diode is connected in parallel between both ends of the solenoid to form a closed loop with the solenoid so that residual current, that is, induced voltage, can be consumed. At this time, when the solenoid is turned off, there is a delay in consumption of residual current as much as the L/R time constant due to the inductance and resistance components of the solenoid. As a result, there is a delay in the responsiveness of the return movement of the electromagnet solenoid as much as the remaining residual current. That is, even if voltage is not applied from the power supply unit, the solenoid does not turn off immediately, and the solenoid can remain on for a certain period of time due to the residual current. Due to this, there is a problem in that the responsiveness is degraded. In the case when an electromagnetic solenoid is applied to switch between four-wheel drive and two-wheel drive, fuel consumption increases due to a switching delay between four-wheel drive and two-wheel drive, thereby degrading the vehicle fuel efficiency.

As shown in FIG. 2, it may be configured with a low-side switch and a freewheeling diode. When the low-side switch is turned on, voltage is applied to the solenoid. When the low-side switch is turned off, the voltage application from the battery, which is the power supply unit, is blocked, but an induced voltage is generated inside the solenoid due to the inductance value and residual current of the solenoid. A freewheeling diode is connected in parallel between both ends of the solenoid to form a closed loop with the solenoid so that residual current, that is, induced voltage, can be consumed. At this time, when the solenoid is turned off, there is a delay in consumption of residual current as much as the L/R time constant due to the inductance and resistance components of the solenoid. As a result, there is a delay in the responsiveness of the return movement of the electromagnet solenoid as much as the remaining residual current. That is, even if voltage is not applied from the power supply unit, the solenoid does not turn off immediately, and the solenoid can remain on for a certain period of time due to residual current. Due to this, there is a problem in that the responsiveness is degraded. In the case when an electromagnetic solenoid is applied to switch between four-wheel drive and two-wheel drive, fuel consumption increases due to a switching delay between four-wheel drive and two-wheel drive, thereby degrading the vehicle fuel efficiency.

As shown in FIGS. 1 and 2, when a freewheeling diode is used, the induced voltage (residual current) is consumed only within the closed loop, so the responsiveness becomes slow. To prevent this delay in response, the solenoid controller 100 according to an embodiment of the present invention uses a clamping element. The clamping element may include a first clamping element 120 and a second clamping element 130.

The first clamping element 120 connects one end of the solenoid 300 and the power supply unit 200, and the second clamping element 130 connects one end of the solenoid 300 and the ground 400. Here, ground 400 may be ground (GND) and may mean the relatively lowest voltage of the controller. For example, it may refer to the (−) terminal of the power supply unit 200. The clamping element blocks a voltage higher than the clamping voltage of the clamping element and limits (clamps) the voltage at both ends to the clamping voltage, and may include one of a Zener diode or a TVS diode.

Zener diode is a constant voltage device using the Zener effect that operates like a regular diode in the forward bias state, in which a positive voltage is applied to the anode and a negative voltage is applied to the cathode, while it is a limiting device in the reverse bias state, in which a negative voltage is applied to the anode and a positive voltage is applied to the cathode so that the current is blocked up to the breakdown voltage (Zener voltage) even if reverse voltage is applied, but current flows when the reverse voltage is greater than the breakdown voltage so that a voltage greater than the breakdown voltage is not applied. That is, the Zener diode operates like a normal diode in a forward direction when forward biased, that is, when the anode voltage is greater than the cathode voltage. Conversely, when reverse bias, that is, the cathode voltage is greater than the anode voltage but less than the clamping voltage, the flow of current in a reverse direction is blocked, and when it is greater than the clamping voltage, current flows in a reverse direction. In other words, current can be allowed to flow or blocked according to the magnitude of the reverse bias voltage.

Transient voltage suppressor (TVS) diode is an instantaneous voltage suppression diode, which is a voltage suppression device to protect the circuit from overvoltage transients when an overvoltage occurs. Using these characteristics, it can operate like a Zener diode. Both Zener diodes and TVS diodes are devices that clamp voltage to a clamping voltage, and they conduct when a voltage greater than the clamping voltage is applied in reverse. Using the characteristics of these clamping elements, the residual current of the solenoid can be consumed quickly.

The first clamping element 120 is disposed to connect the solenoid 300 and the power supply unit 200. At this time, the clamping voltage of the first clamping element 120 may be higher than the voltage of the power supply unit 200. By using the first clamping element 120 whose clamping voltage is higher than the voltage of the power supply unit 200, the residual current of the solenoid 300 flows toward the power supply unit 200 through the first clamping element 120 according to the magnitude of the induced voltage of the solenoid 300, but current can be prevented from flowing from the power supply unit 200 to the solenoid 300 through the first clamping element 120. The second clamping element 130 is disposed to connect between the solenoid 300 and the ground 400, and the clamping voltage of the second clamping element 130 may be the same as the clamping voltage of the first clamping element 120. The clamping voltage can be set according to the size of the battery voltage. For example, the clamping voltage can be set between 14 to 35 V when the battery voltage is 12 to 14 V. The clamping voltage may be greater than the voltage of the power supply unit 200, but may be set below the maximum rated voltage of the power supply unit 200 to prevent burning damage when a current is applied to the power supply unit 200. If the power supply unit 200 is a battery, it may be set to less than or equal to the maximum rated voltage of the battery. For example, the clamping voltage can be set to 30 V. According to the set clamping voltage, a clamping element with a corresponding clamping voltage can be selected and applied.

The directions in which the first clamping element 120 and the second clamping element 130 are connected to the solenoid 300 may be opposite to each other. The first clamping element 120 may be connected to the solenoid 300 in a reverse direction, and the second clamping element 130 may be connected to the solenoid 300 in a forward direction. The anode of the first clamping element 120 may be connected to one end of the solenoid 300, and the cathode may be connected to the power supply unit 200. The first clamping element 120 is not connected to the ground 400. In contrast, the cathode of the second clamping element 130 may be connected to one end of the solenoid 300, and the anode may be connected to the ground 400. The anode of the second clamping element 130 may be connected to the (−) terminal of the power supply unit 200.

As the switching unit 110 operates, the voltage of the power supply unit 200 is applied to the solenoid 300, causing current to flow into the solenoid 300. At this time, when the power of the power supply unit 200 is not applied to the solenoid 300 by the switching unit 110, an induced voltage is generated in the solenoid 300 due to residual current, and the path through which the residual current is discharged may vary according to the magnitude of the induced voltage.

When the magnitude of the induced voltage that occurs in the solenoid 300 corresponds to between the clamping voltage and the voltage of the power supply unit 200, current may be discharged toward the power supply unit 200 through the first clamping element 120. When the magnitude of the induced voltage that occurs in the solenoid 300 corresponds to between the clamping voltage and the voltage of the power supply unit 200, since the induced voltage is greater than the voltage of the power supply unit 200, a voltage is applied to the first clamping element 120 in a forward direction, thereby forming a path being connected to the power supply unit 200 through the first clamping element 120. Through the corresponding path, the residual current of the solenoid 300 is discharged to the power supply unit 200. Considering the voltage drop of the first clamping element, when the clamping voltage and the voltage of the power supply unit 200 are greater than a predetermined voltage (for example, 0.7 V), current may be discharged toward the power supply unit 200 through the first clamping element 120. The power supply unit 200 may be a battery, and the battery, which is the power supply unit 200, may be charged by the current being discharged to the power supply unit 200. In this way, the induced voltage can be used to charge the battery rather than simply consuming it. At this time, if the magnitude of the induced voltage that occurs in the solenoid 300 corresponds to between the clamping voltage and the voltage of the power supply unit 200, the second clamping element 130 is applied with a voltage in a reverse direction, and since the induced voltage is not greater than the clamping voltage, current does not flow through the second clamping element 130.

When the magnitude of the induced voltage that occurs in the solenoid 300 is greater than the clamping voltage, current may be discharged toward the ground 400 through the second clamping element 130. A large current flows in a reverse direction of the second clamping element 130, thereby forming a path toward the ground 400 when the magnitude of the induced voltage that occurs in the solenoid 300 is greater than the clamping voltage of the second clamping element 130 that applies voltage in a reverse direction. Through this path, the residual current of the solenoid 300 is quickly discharged to the ground 400. Since the magnitude of the induced voltage that occurs in the solenoid 300 is greater than the clamping voltage, a voltage is applied to the first clamping element 120 in a forward direction, and although a path connecting to the power supply unit 200 is formed through the first clamping element 120, since the current is quickly discharged toward the ground 400 being formed through the second clamping element 130, at this time, the current is discharged through the path toward the second clamping element 130 rather than toward the first clamping element 120. Through this, when the magnitude of the induced voltage that occurs in the solenoid 300 is greater than the clamping voltage, it is possible to prevent the risk of burning damage to the battery or circuit being connected to the battery due to a large voltage being applied to the battery, which is the power supply unit 200.

When the magnitude of the induced voltage that occurs in the solenoid 300 is smaller than the voltage of the power supply unit 200, current may be discharged to the ground through the switching unit 110. When the magnitude of the induced voltage that occurs in the solenoid 300 is smaller than the voltage of the power supply unit 200, both the first clamping element 120 and the second clamping element 130 are applied with voltage in a reverse direction, all current flows to the first clamping element 120 and the second clamping element 130 are blocked. At this time, the residual current may be discharged toward the ground 400 through the switching unit 110. The switching unit 110 blocks the connection with the power supply unit 200, but can be connected to the ground 400.

The switching unit 110 may include one or more high-side switches and one or more low-side switches. The switching unit 110 may be configured as a half bridge, or as a full bridge, that is, an H-bridge.

The switching unit 110 configured as an H-bridge comprises: a first high-side switch and a first low-side switch being connected to the power supply unit 200; and a second high-side switch and a second low-side switch being connected to the power supply unit 200, wherein a node between the first high-side switch and the first low-side switch is connected to one end of the solenoid 300, and wherein a node between the second high-side switch and the second low-side switch may be connected to the other end of the solenoid 300. When the solenoid 300 is turned on, the first high-side switch and the second low-side switch are turned on to apply the voltage of the power supply unit 200 to the solenoid 300, and when the solenoid 300 is turned off, the first high-side switch and the second low-side switch are turned off to block the voltage of the power supply unit 200 from being applied to the solenoid 300.

When the switching unit 110 is configured as an H-bridge, the solenoid controller according to an embodiment of the present invention can be implemented as shown in the circuit diagram of FIG. 4. The power supply unit 200 is a battery; the switching unit 110 is implemented as an H-bridge being configured as four switches H1, H2, L1, and L2; and a first clamping element 120 and a second clamping element 130 can be implemented as a Zener diode. An input capacitor AL-CAP may be connected to the input stage of the battery. The node between the first high-side switch H1 and the first low-side switch L1 configuring the H-bridge is connected to one end A of the solenoid 300, and a node between the second high-side switch H2 and the second low-side switch L2 may be connected to the other end B of the solenoid 300. Zener diode T1, which is the first clamping element 120, has an anode connected to one end A of the solenoid 300 and a cathode connected to a battery that is the power supply unit 200. Zener diode T2, which is the second clamping element 130, has an anode connected to the (−) terminal or ground of the battery that is the power supply unit 200, and a cathode connected to one end A of the solenoid 300.

Each of the switches of the switching unit 110 may be an FET, but is not limited thereto. Each of the switches can be controlled by a control unit (not shown), and can be controlled by applying a gate voltage to the switch by a gate driver.

When turning on the solenoid 300, the first high-side switch H1 and the second low-side switch L2 are turned on, so that a path is formed sequentially through the power supply unit 200, the first high-side switch H1, one end A of the solenoid 300, the solenoid, the other end B of the solenoid 300, and the second low-side switch L2 so that a current flows therethrough, and the voltage of the power supply unit 200 is applied to the solenoid 300.

At this time, when the solenoid 300 is turned off, it can operate as shown in FIG. 5. First, the first high-side switch H1 and the second low-side switch L2 are turned off (S2) according to the electromagnet solenoid OFF command (S1) that turns off the solenoid. Even if the high-side switch H1 and the second low-side switch L2 are turned off, the solenoid does not turn off immediately, and the induced voltage V_L=L(di/dt) is generated by the residual current (S3). At this time, the size of the induced voltage varies depending on the inductance value of the solenoid. If the inductance value of the solenoid is large, the size of the induced voltage also becomes large, and the induced voltage may cause burning damage in the switching element, FET or gate driver. For example, the inductance value of the solenoid may have a value greater than 5 mH, and in this case, burning damage to the FET may occur.

At this time, depending on whether the magnitude of the induced voltage that occurs corresponds to between the clamping voltage and the voltage of the power supply unit, it is determined whether a path to the first clamping element T1 will be formed. When the induced voltage is below the battery voltage (S4=NO), there is a low possibility of burning damage to the FET, so at this time, a current discharge path may not be formed, or the residual current may be discharged through a switching element. For example, by turning on the first low-side switch L1, a path is formed sequentially through the one end A of the solenoid 300, the first low-side switch L1, and the (−) terminal of battery to discharge the residual current therethrough. When the magnitude of the induced voltage corresponds to between the clamping voltage and the voltage of the power supply unit (S4=YES), a forward voltage is applied to the first clamping element T1, so that a path through which current is discharged to the battery through the first clamping element T1, that is, a path V_L PATH through which induced voltage is consumed, is formed (S5).

In addition, whether a path to the second clamping element T2 will be formed is determined depending on whether the magnitude of the induced voltage that occurs is greater than the clamping voltage. When the induced voltage is less than the clamping voltage (S6=NO), no current flows through the second clamping element T2 due to the clamping voltage, and the current is discharged through the path to the first clamping element T1. When the magnitude of the induced voltage is greater than the clamping voltage (S6=YES), the reverse voltage of the second clamping element T2 is greater than the clamping voltage, and the ground ((−) terminal of the battery), a path through which current is discharged, that is, a path V_L PATH through which induced voltage is consumed is formed (S7). When all residual current is discharged, the electromagnet solenoid is turned off (S8).

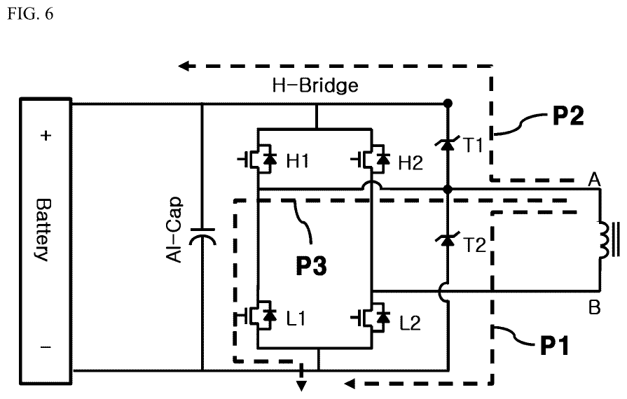

That is, depending on the magnitude of the induced voltage, residual current may be discharged through three paths as shown in FIG. 6. When the induced voltage is greater than the clamping voltage, current is discharged to the path P1 being connected to the ground through the first clamping element T2; when the induced voltage is between the clamping voltage and the battery voltage, current is discharged to the path P2 being connected to the battery through the first clamping element T1; and when the induced voltage is lower than the battery voltage, current may be discharged to the path P3 being connected to the ground through the first low-side switch L1 of the switching unit.

When the induced voltage is greater than the clamping voltage, current is released through P1; when the induced voltage is consumed due to current discharge along the P1 path and falls below the clamping voltage, current is discharged through the path P2 rather than the path P1; and when the induced voltage is consumed due to current discharge along the path P2 and falls below the battery voltage, current is discharged through the path P3 rather than the path P2. In other words, depending on the size of the induced voltage, the current discharge path may vary in the order of P1, P2, and P3. For example, the battery voltage may be 12 V and the clamping voltage may be 30 V. When the induced voltage is 35 V, the voltage greater than the clamping voltage of 30 V is consumed to ground through the path P1, and when the induced voltage is 12 to 30 V, a voltage greater than 12 V, which is the battery voltage, is consumed as the battery voltage through the path P2. When the induced voltage is below 12V, there is little chance of burning damage to the switching element, so at this time, it is consumed to the ground through the path P3 and all the residual current is consumed.

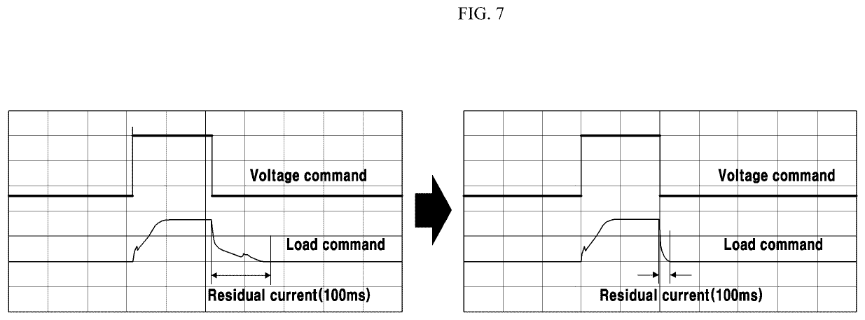

As described above, residual current can be consumed quickly by using a clamping element to form a current discharge path toward the power supply unit 200 or the ground 400 depending on the magnitude of the induced voltage. Through this, as shown in FIG. 7, the residual current time can be reduced. It can be seen that the residual current time of 600 ms, which occurs when using the freewheeling diode of FIG. 1 or FIG. 2, is reduced to 100 ms when a clamping element is used. It can be seen that the OFF operation time of the solenoid is improved as much as the residual current time, and the responsiveness of the electromagnetic solenoid is improved.

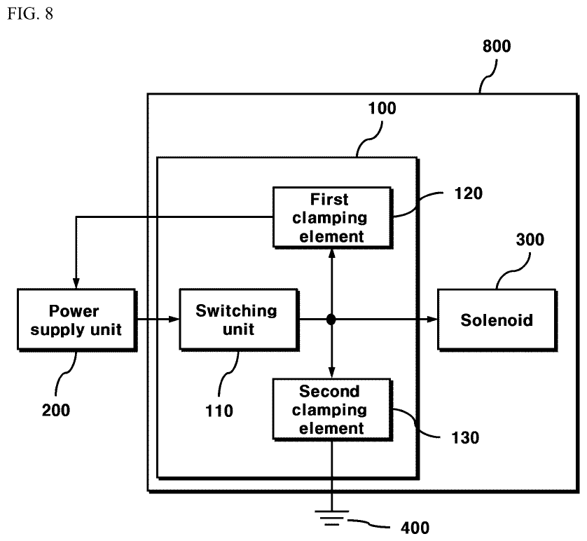

FIG. 8 is a block diagram of a vehicle motor according to an embodiment of the present invention. The detailed description of each component in FIG. 8 corresponds to the detailed description of the solenoid controller described with reference to FIGS. 1 to 7, and overlapping descriptions will be briefly described hereinafter.

The vehicle motor 800 according to an embodiment of the present invention includes: a solenoid 300 being driven according to voltage input; a solenoid controller 100 that controls solenoid 300, wherein the solenoid controller 100 includes: a switching unit 110 that outputs the voltage being inputted from the power supply unit 200 to the solenoid 300; a first clamping element 120 connecting one end of the solenoid 300 and the power supply unit 200; and a second clamping element 130 connecting one end of the solenoid 300 and the ground 400. Here, the clamping voltage of the first clamping element 120 is higher than the voltage of the power supply unit 200. The vehicle motor 800 according to an embodiment of the present invention may be a motor that switches the driving method of the vehicle between two-wheel drive (2WD) and four-wheel drive (4WD).

When the power from the power supply unit is not applied to the solenoid by the switching unit, and when induced voltage occurs in the solenoid due to residual current, a path that consumes the induced voltage is formed so that residual current can be discharged and consumed. At this time, when the magnitude of the induced voltage that occurs in the solenoid corresponds to between the clamping voltage and the voltage of the power supply unit, current is discharged toward the power supply unit through the first clamping element; when the magnitude of the induced voltage that occurs in the solenoid is greater than the clamping voltage, current is emitted toward the ground through the second clamping element; and when the magnitude of the induced voltage that occurs in the solenoid is smaller than the voltage of the power supply unit, current may be discharged to the ground through the switching unit. Here, the first clamping element and the second clamping element may include at least one of a Zener diode or a TVS diode.

Meanwhile, the embodiments of the present invention can be implemented as computer readable codes on a computer readable recording medium. The computer readable recording medium includes all types of recording devices in which data readable by a computer system is stored.

As for examples of computer readable recording media, there are ROM, RAM, CD-ROM, magnetic tape, floppy disk, and optical data storage device; in addition, the computer readable recording medium is distributed over networked computer systems; and computer readable code can be stored and executed in a distributed manner. In addition, functional programs, codes, and code segments for implementing the present invention can be easily inferred by programmers in the technical field to which the present invention belongs.

Those skilled in the art related to the present embodiment will be able to understand that it may be implemented in a modified form within a range that does not deviate from the essential characteristics of the above description. Therefore, the disclosed methods are to be considered in an illustrative rather than a limiting sense. The scope of the present invention is shown in the claims rather than the foregoing description, and all differences within the equivalent scope shall be construed as being included in the present invention.

1. A solenoid controller comprising:
a switching unit configured to output a voltage inputted from a power supply unit to a solenoid;
a first clamping element connecting one end of the solenoid and the power supply unit; and
a second clamping element connecting one end of the solenoid and a ground,
wherein a clamping voltage of the first clamping element is higher than the voltage of the power supply unit.

2. The solenoid controller according to claim 1, wherein when power of the power supply unit is not applied to the solenoid by the switching unit, and when a magnitude of an induced voltage that occurs in the solenoid corresponds to between the clamping voltage and the voltage of the power supply unit, current is discharged toward the power supply unit through the first clamping element.

3. The solenoid controller according to claim 1, wherein when power of the power supply unit is not applied to the solenoid by the switching unit, and when a magnitude of an induced voltage that occurs in the solenoid is larger than the voltage of the power supply unit, current is discharged toward the ground through the second clamping element.

4. The solenoid controller according to claim 1, wherein when power of the power supply unit is not applied to the solenoid by the switching unit, and when a magnitude of an induced voltage that occurs in the solenoid is smaller than the voltage of the power supply unit, current is discharged to the ground through the switching unit.

5. The solenoid controller according to claim 1, wherein the first clamping element and the second clamping element comprise at least one of a Zener diode or a TVS diode.

6. The solenoid controller according to claim 5, wherein the first clamping element has an anode connected to one end of the solenoid and a cathode connected to the power supply unit, and
wherein the second clamping element has a cathode connected to one end of the solenoid and an anode connected to the ground.

7. The solenoid controller according to claim 1, wherein the power supply unit comprises a battery.

8. The solenoid controller according to claim 1, wherein the switching unit comprises:
a plurality of high-side switches and a plurality of low-side switches that are complementarily conducting to one another.

9. The solenoid controller according to claim 1, wherein the switching unit comprises:
a first high-side switch and a first low-side switch connected to the power supply unit; and
a second high-side switch and a second low-side switch connected to the power supply unit,
wherein a node between the first high-side switch and the first low-side switch is connected to one end of the solenoid, and
wherein a node between the second high-side switch and the second low-side switch is connected to the other end of the solenoid.

10. The solenoid controller according to claim 9, wherein when the solenoid is turned off, the first high-side switch and the second low-side switch are turned off.

11. A solenoid motor comprising:
a solenoid driven according to a voltage input; and
a solenoid controller configured to control the solenoid,
wherein the solenoid controller comprises:
a switching unit configured to output a voltage inputted from a power supply unit to the solenoid;
a first clamping element connecting one end of the solenoid and the power supply unit; and
a second clamping element connecting one end of the solenoid and a ground,
wherein a clamping voltage of the first clamping element is higher than the voltage of the power supply unit.

12. The solenoid motor according to claim 11, wherein when power of the power supply unit is not applied to the solenoid by the switching unit, and when a magnitude of an induced voltage that occurs in the solenoid corresponds to between the clamping voltage and the voltage of the power supply unit, current is discharged toward the power supply unit through the first clamping element.

13. The solenoid motor according to claim 11, wherein when power of the power supply unit is not applied to the solenoid by the switching unit, and when a magnitude of an induced voltage that occurs in the solenoid is larger than the voltage of the power supply unit, current is discharged toward the ground through the second clamping element.

14. The solenoid motor according to claim 11, wherein when power of the power supply unit is not applied to the solenoid by the switching unit, and when a magnitude of an induced voltage that occurs in the solenoid is smaller than the voltage of the power supply unit, current is discharged to the ground through the switching unit.

15. The solenoid motor according to claim 11, wherein the first clamping element and the second clamping element comprise at least one of a Zener diode or a TVS diode.

16. The solenoid motor according to claim 15, wherein the first clamping element has an anode connected to one end of the solenoid and a cathode connected to the power supply unit, and
wherein the second clamping element has a cathode connected to one end of the solenoid and an anode connected to the ground.

17. The solenoid motor according to claim 11, wherein the power supply unit comprises a battery.

18. The solenoid motor according to claim 11, wherein the switching unit comprises:
a plurality of high-side switches and a plurality of low-side switches that are complementarily conducting to one another.

19. The solenoid motor according to claim 11, wherein the switching unit comprises:
a first high-side switch and a first low-side switch connected to the power supply unit; and
a second high-side switch and a second low-side switch connected to the power supply unit,
wherein a node between the first high-side switch and the first low-side switch is connected to one end of the solenoid, and
wherein a node between the second high-side switch and the second low-side switch is connected to the other end of the solenoid.

20. The solenoid motor according to claim 19, wherein when the solenoid is turned off, the first high-side switch and the second low-side switch are turned off.
